(19) United States
(12) Patent Application Publication
(10) Pub. No.: US 2005/0088173 A1
(43) Pub. Date: Apr. 28, 2005

(54) Method and apparatus for tunable magnetic force interaction in a magnetic force microscope

(76) Inventor: David W. Abraham, Croton-on-Hudson, NY (US)

Correspondence Address: Moser, Patterson & Sheridan;Suite 100, 595 Shrewsbury Avenue, Shrewsbury, NJ, 07702, US

(21) Appl. No.: 10/693,240

(22) Filed: Oct. 24, 2003

(51) Int. Cl. G01R 33/00; G01N 27/72

(52) U.S. Cl. 324/244; 324/224; 73/105

(57) ABSTRACT

The present invention is a method an apparatus for tunable magnetic force interaction for a magnetic force microscope. In one embodiment, the magnetic moment of a probe tip is oscillated using a time-varying heat source. The magnetic field interaction between the probe tip and a sample is thus modulated, substantially separating the magnetic force components of a measurement from non-magnetic components at any time and position over the sample. This simplifies the measurement process and also provides measurements of sample properties that are more purely magnetic than measurements achieved by existing magnetic force microscopy techniques.

### BACKGROUND

The invention relates generally to magnetic force microscopy, and relates more particularly to tips for use in magnetic force microscopes. Specifically, the present invention is a method and apparatus for tuning magnetic force interactions in a magnetic force microscope.

Magnetic force microscopy (MFM) is a powerful method for imaging magnetic domains in materials with submicron resolution. Magnetic force microscopes produce images of a magnetic structure at a sample surface through the detection of the force between a magnetic cantilever-mounted probe tip and the sample. It is reasonably non-invasive (i.e., it does not significantly affect the sample magnetization in most cases), can detect extremely small forces (and therefore is very sensitive to domain structure), is vector in nature, and can be performed non-destructively.

In spite of these advantages, however, the most common methods of performing MFM are difficult to interpret in a straightforward manner because the image that is obtained is a composite of both magnetic and non-magnetic forces. Some conventional imaging modes have attempted to address this merely by adjusting the tip of the microscope so that the magnetic forces are dominant, but this does not entirely eliminate the non-magnetic forces. Alternatively, the tip can be traced at reasonably high-force loads so that the distance from the tip to the sample is reduced to the point that surface (i.e., non-magnetic) forces dominate for a first scan over the sample. Then, the tip is retracted a pre-determined distance for the recorded surface trace, and a second scan is made over the sample. This concept relies on the assumption that the surface force at the constant tip/sample separation is not only constant, but vastly reduced, depending on the lift height used for the second scan. The resultant magnetic image is obtained from force or force-gradient modulation of the sensing cantilever oscillation.

Variations on the above-described methods rely on the separation of the magnetic and non-magnetic forces by their different height dependencies. These methods are inherently flawed, however, as they yield imperfect subtraction of the two main force components. Furthermore, because such methods rely on repeat scans, additional imperfections in image subtraction due to drift and scanner nonlinearities can lead to further degradation of the magnetic information. As a final consideration, methods that employ repeat scans are inherently slower than methods in which only one scan is necessary.

Thus, there is a need for a method and apparatus for magnetic force microscopy that efficiently and accurately provides for true measurement of sample properties.

### SUMMARY OF THE INVENTION

In one embodiment, the present invention is a method and an apparatus for tunable magnetic force interaction for a magnetic force microscope. In one embodiment, the magnetic moment of a probe tip is oscillated using a time-varying heat source. The magnetic field interaction between the probe tip and a sample is thus turned on or off selectively, or modulated between two values, thereby substantially separating the magnetic force components of a measurement from non-magnetic components at any time and position over the sample. This not only simplifies the measurement process, but also provides measurements of sample properties that are more purely magnetic than measurements achieved by existing magnetic force microscopy techniques. Thus, the method and apparatus disclosed enable substantially accurate magnetic measurement of a sample in a single pass of the scanned probe tip.

### BRIEF DESCRIPTION OF THE DRAWINGS

So that the manner in which the above recited embodiments of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic view of one embodiment of a magnetic force microscope that may be advantageously adapted to benefit from the present invention;

FIG. 2 illustrates a schematic view of one embodiment of a probe tip for use in the magnetic force microscope of FIG. 1, wherein the tip is heated externally by a laser;

FIG. 3 illustrates a schematic view of one embodiment of a probe tip for use in the magnetic force microscope of FIG. 1, wherein the tip is externally heated by a two-conductor electrode;

FIG. 4 illustrates a schematic view of one embodiment of a probe tip for use in the magnetic force microscope of FIG. 1, wherein a transparent tip is heated by a laser beam in the tip core;

FIG. 5 is a graph illustrating the oscillation of magnetic moment with temperature for one embodiment of a probe tip coating material; and

FIG. 6 is a flow diagram illustrating one embodiment of a method for performing magnetic force microscopy according to the present invention.

To facilitate understanding, identical reference numerals have been used, where possible, to designate identical elements that are common to the figures.

### DETAILED DESCRIPTION

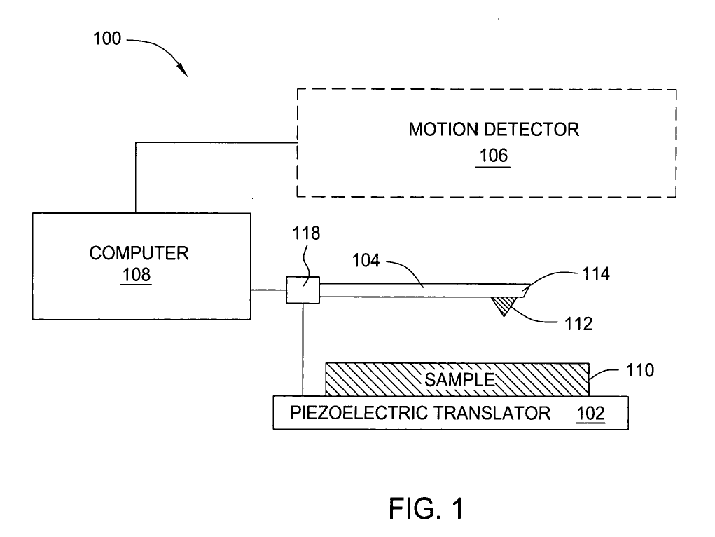

FIG. 1 is a simplified schematic diagram of one embodiment of an illustrative magnetic force microscope 100 that may be advantageously adapted to benefit from the present invention. Those skilled in the art will appreciate that other configurations and embodiments of atomic and magnetic force microscopes may be used to advantage with the present invention. The microscope 100 comprises a sample support, e.g., a piezoelectric translator 102, a cantilever 104, a motion detector 106, a laser 120 and a computer 108. The cantilever 104 is positioned above the piezoelectric translator 102, which is adapted to support a sample material 110 thereon. In one embodiment, the sample 110 comprises a thin magnetic film deposited upon a substrate (e.g., silicon or sapphire). The cantilever 104 further comprises a heated probe 112 at an end 114 that hovers directly above the piezoelectric translator 102. The motion detector 106 is positioned above the cantilever 104.

In the embodiment illustrated, the cantilever 104 is coupled to an oscillator 118 that is adapted to excite the cantilever 104 into resonance oscillation. The oscillatory deflection of the cantilever 104 is detected by the motion detector 106. In one embodiment, the motion detector 106 is an optical detector, e.g., a quadrant detector, that accurately detects the motion of a laser light focused on the cantilever 104. In further embodiments, the motion detector 106 is any conventional motion detector, including, but not limited to, a capacitive sensor or a piezoelectric cantilever. Light reflected from the cantilever 104 is also detected by the optical detector 106, which then sends an output signal to the computer 108. The computer 108 converts the output signal to a value indicative of an amplitude of deflection.

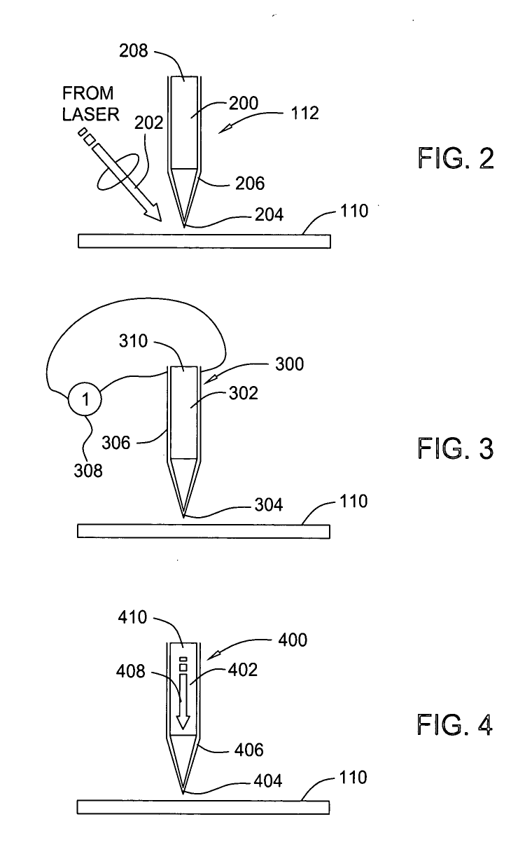

FIG. 2 illustrates a schematic view of one embodiment of a heated probe 112 for use in the magnetic force microscope 100 of FIG. 1. The probe 112 comprises a tapered tip 200 having a first end 204 that is adapted for observing a sample and a second end 208 adapted to be coupled to the cantilever 104. In one embodiment, the tip 200 is formed from a material having temperature dependent magnetic properties. In another embodiment, the tip 200 comprises a silicon material that is coated with a thin film or coating 206 of a material having temperature-dependent magnetic properties. In one embodiment, the tip 200 is formed from or coated with a ferromagnetic, ferrimagnetic or paramagnetic material. A laser (not shown) is positioned proximate to the probe 112 and is adapted to emit a beam 202 that is focused on the first end 204 of the tip 200.

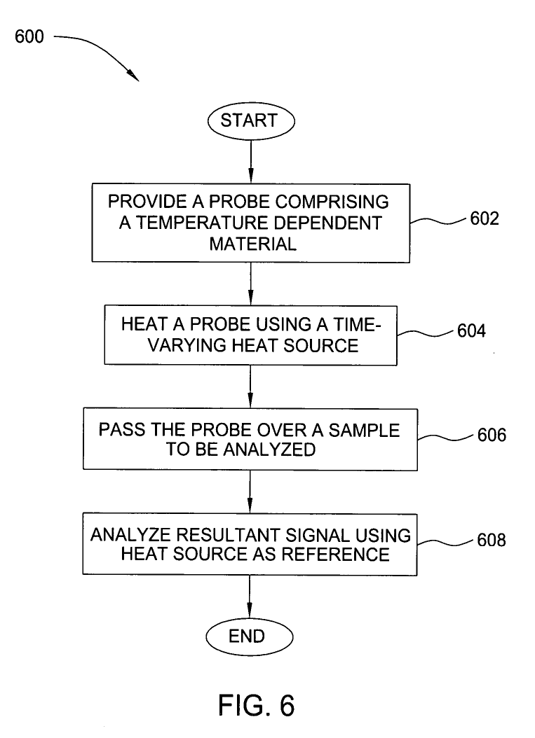

FIG. 6 is a flow diagram illustrating one embodiment of a method 600 for performing magnetic force microscopy according to the present invention, for example using the microscope and probe configuration disclosed with reference to FIGS. 1 and 2. As discussed above with reference to FIGS. 1 and 2, the probe 112 is formed of or coated with a temperature dependent material (step 602). Referring simultaneously to FIGS. 1, 2 and 6, in one embodiment, the laser is adapted (at step 604) to emit a series of rapid pulses aimed at the tip 200 to quickly heat the tip coating 206. The pulses are arranged so that the temperature of the probe tip 200 rises above ambient during the pulse, and substantially cools during the pulse-off time. The magnetic properties of the tip coating material are temperature-dependent, and the rapid pulsed heating of the tip 200 modulates the magnetization of the coating 206 so that the magnetic field interaction between the tip 200 and the sample 110 is modulated.

In one embodiment, the tip 200 is periodically heated at a frequency that is at or near a mechanical resonance of the cantilever 104. The resonance frequency used for temperature modulation is chosen to be distinct from the mechanical resonance used for topographic feedback control. The detection of a magnetic signal is performed by measuring the tip oscillation at this particular resonance frequency. This effectively separates the magnetic force component from the non-magnetic (e.g., topographic) component at any given time and position over the sample 110, making the tip oscillation observed by the optical detector 106 a function of solely magnetic film properties. This enables substantially enhanced and true magnetic measurement of the sample properties in a single pass of the microscope (step 606). Alternatively, the tip 200 could be periodically heated at a frequency that is different from the mechanical resonance of the cantilever 104, and the magnetic force could be detected according other conventional or unconventional means. After the microscope has passed over the sample (step 606), the resultant signal is analyzed in step 608. In one embodiment, the heat source is used as a reference in a lock-in detection of the magnetic signal.

In another embodiment, the magnetic properties of the sample 110 are more temperature dependent in the regime of temperature chosen to operate the microscope 100 than are the properties of the tip coating material. In such a case, the laser is positioned to emit a beam aimed at the underside of a substantially transparent substrate, upon which a thin magnetic film (comprising, for example, cobalt, iron, nickel and/or alloys thereof, among others, in combination with other non-magnetic elements) is deposited, to provide rapidly varying temperature at the magnetic thin film. Such a technique could be particularly well-suited, for example, for studying disk drive media on glass substrates or thin magnetic films on transparent substrates.

In one embodiment, the tip coating material is a ferromagnetic or paramagnetic material having a low Curie temperature. The magnetic moment as a function of temperature monotonically decreases for both ferromagnetic and paramagnetic materials, and the magnetic moment is finally “quenched” at the Curie temperature. Modulation of the magnetic moment for a low-Curie temperature material is thus more feasible for an obtainable range of temperatures than is the modulation for a high-Curie temperature material. In one embodiment, a low Curie temperature material has a Curie temperature that is approximately 50-100 degrees Celsius above ambient, so that the heating can comfortably approach the Curie temperature without mechanically distorting the microscope 100 due to thermal expansion of microscope components. For example, in one embodiment, the magnetic moment of the tip 200 is modulated within a temperature range of tens of degrees Celsius, and in another embodiment, the temperature range for modulation is between five and fifty degrees Celsius.

In another embodiment, the tip coating material is a ferrimagnetic material, such as a (Gd, Tb, Dy)—(Fe, Co) alloy (e.g., Gd₂₃Fe₇₇, Gd₂₄Fe₇₆, Tb₁₉Fe₈₁, TB₂₁Fe₇₉, Dy₁₇Fe₈₃, Dy₂₁Fe₇₉, among others). Ferrimagnetic materials are unique in that they are composed, microscopically, of two different kinds of atoms, the magnetic moments of which are different and typically point in opposite directions. Thus the temperature dependent properties of the ferrimagnetic material are variable, i.e., at a first temperature, the magnetic moment of a first set of atoms will dominate, and at a second temperature the properties of a second set of atoms will dominate. At an intermediate “compensation temperature”, the magnetic moments of the first and second sets of atoms are equal and opposite, resulting in a net magnetic moment of zero for the ferrimagnetic material. However, if the ferrimagnetic tip coating material is heated at a temperature that deviates from the compensation temperature (i.e., higher or lower), the magnetic moment will increase due to the domination of one of the sublattices or atoms that make up the ferrimagnetic material, which become imbalanced as the heating temperature moves away from the compensation temperature. The magnetization of the tip 200 will then oscillate at a frequency that is double the frequency of the thermal modulation. Thus one cycle in temperature changes will achieve two cycles in moment change (i.e., one at a temperature above compensation, and one at a temperature below compensation). A further advantage of this embodiment is that inadvertent signal due to thermal expansion of the microscope components can be isolated, since magnetic signal is expected to appear at double the heating frequency.

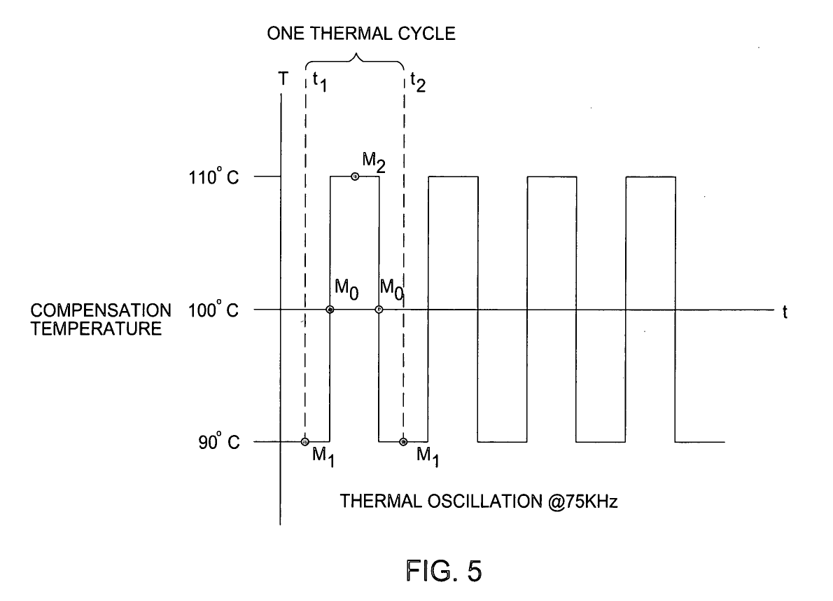

FIG. 5 is a graph illustrating the effect of temperature modulation on the magnetic moment of a ferromagnetic or ferrimagnetic material. For example, in one embodiment, the tip 200 is coated with a ferrimagnetic material having a compensation temperature of 100 degrees Celsius, and the tip is heated at a temperature that continuously oscillates between 90 and 110 degrees Celsius. Thus at 100 degrees Celsius (i.e., compensation), the material has no moment or a negligible moment M₀. As the temperatures deviates from compensation, i.e. to either 90 and 110 degrees Celsius, the magnetic moment increases to moment M₁ or M₂, respectively (i.e., where M₁ and M₂ are finite values greater than zero). Therefore, as the temperature oscillates through one cycle from 90 to 110 degrees Celsius (i.e., during the time interval from t₁ to t₂), the magnetic moment of the material oscillates from M₁ (high) to M₀ (low) to M₂ (high) to M₀ (low) and back to M₁ (high). Thus the magnetic moment completes two cycles from t₁ to t₂, while the temperature completes only one cycle from t₁ to t₂. Therefore, if the heating temperature were oscillated between these temperatures at 75 kHz, the magnetization of the ferrimagnetic material would oscillate at a frequency of approximately 150 kHz, or double the frequency of the heating temperature oscillation. In another embodiment, the tip 200 is coated with a ferromagnetic material having a Curie temperature of approximately 110 degrees Celsius, and the tip is heated at a temperature that continuously oscillates between 90 and 130 degrees Celsius. The magnetic moment of the ferromagnetic material will decrease as the temperature increases, so that the moment M₁ at 90 degrees Celsius decreases to M₀ at 100 degrees Celsius and is substantially quenched at the lowest moment M₂ at 110 degrees Celsius. As the temperature drops back toward 90 degrees Celsius, the magnetic moment increases as it approaches M₁. In this case, the magnetic signal would appear at the heating frequency of 75 kHz.

Thus, the thermal and magnetic effects may be separated by observing the oscillation of the tip 200. If the frequency of the tip's magnetic oscillation is double the frequency of the thermal input, this phenomenon may be presumed to be a result of the magnetic effects. This may be verified by adjusting the operating temperature to one slightly removed from the compensation temperature and observing the effect on the frequency of the tip's magnetic oscillations.

FIG. 3 illustrates a schematic view of another embodiment of a heated probe 300 for use in the magnetic force microscope 100 of FIG. 1. The probe 300 is substantially similar to the probe 112 illustrated in FIG. 2 and comprises a tapered tip 302 having a first end 304 and a second end 310 adapted to be coupled to the cantilever 104. The tip 300 is coated with a magnetic coating 306 to form a two-conductor electrode. A current source 308 is coupled to the tip 300 and is adapted to apply a voltage to the tip 300 so as to form an electrical circuit with the magnetic coating 306. This enables the magnetic coating 306 to be heated, thereby changing its magnetic properties as described above with reference to FIG. 2.

FIG. 4 illustrates a schematic view of another embodiment of a heated probe 400 for use in the magnetic force microscope of FIG. 1. The probe 400 comprises a tapered tip 402 having a first end 404 and a second end 410 adapted to be coupled to the cantilever 104. The tip 402 is formed from a transparent material, and in one embodiment the tip 402 is an optical fiber that has been heated and drawn into a tip configuration. The tip 402 is coated with a magnetic coating 406 that in one embodiment comprises a ferromagnetic, ferrimagnetic or paramagnetic material. A laser (not shown) is positioned to direct a beam 408 down the core of the tip 402. The light is absorbed by the magnetic tip coating 406. In the embodiment where the tip 402 comprises an optical fiber, the optical fiber may absorb some of the light as well.

Thus, the present invention represents a significant advancement in the field of magnetic force microscopy. A probe tip is provided having rapidly adjustable magnetic properties, which allows the magnetic field interaction between the tip and a sample to be turned on or off selectively. This will substantially separate magnetic force components from non-magnetic components when the microscope is in operation, enabling enhanced magnetic measurement of the sample properties.

While foregoing is directed to the preferred embodiment of the present invention, other and further embodiments of the invention may be devised without departing from the basic scope thereof, and the scope thereof is determined by the claims that follow.

1. A method for performing magnetic force microscopy comprising:
providing a probe comprising a material having temperature-dependent magnetic properties, the probe having a tip adapted for observing a surface of a sample; and
heating the probe.

2. The method of claim 1, wherein the probe tip is tapered.

3. The method of claim 1, wherein the step of heating the probe comprises:
heating the probe using a time-varying heat source.

4. The method of claim 1, wherein the probe is coated with the material having temperature-dependent magnetic properties.

5. The method of claim 1, wherein the probe comprises:
a ferromagnetic or paramagnetic material.

6. The method of claim 5, wherein said ferromagnetic or paramagnetic material has a low Curie temperature.

7. The method of claim 1, wherein the probe comprises a ferrimagnetic material.

8. The method of claim 7, wherein the probe comprises a (Gd, Tb, Dy)—(Fe, Co) alloy.

9. The method of claim 5, wherein the step of heating the probe comprises:
oscillating the temperature of the probe over a range of values having a lower limit below a compensation temperature of the probe material and an upper limit above the compensation temperature.

10. The method of claim 1, wherein the step of heating the probe comprises:
focusing a laser on the tapered tip of the probe.

11. The method of claim 10, wherein the step of focusing the laser further comprises:
modulating the laser power that heats the probe tip.

12. The method of claim 1, wherein the step of providing the probe further comprises:
providing a two-conductor electrode to the probe tip.

13. The method of claim 12, wherein the step of heating the probe comprises:
coupling a current source to the probe; and
applying a current to the probe.

14. The method of claim 1, wherein the step of heating the probe comprises:
heating a magnetic coating on the tip from within a core of the probe.

15. The method of claim 14, wherein the probe comprises a transparent material coated with a heat-conducting material.

16. The method of claim 15, wherein the probe comprises an optical fiber pulled to form a probe.

17. The method of claim 15, wherein the step of heating the core of the probe comprises focusing a laser through the core of the probe.

18. A magnetic force microscope comprising:
a cantilever adapted for oscillating, wherein the cantilever has a first end and a second end;
a probe coupled to the second end of the cantilever, wherein the probe has a tip comprising a low Curie temperature material;
a laser adapted for illuminating the second end of the cantilever;
an optical detector adapted for detecting light reflected by the cantilever; and
a heat source adapted for heating the probe.

19. The magnetic force microscope of claim 18, wherein the heat source is a time-varying heat source adapted to modulate heat to the probe.

20. A magnetic force microscope comprising:
a cantilever adapted for oscillating, the cantilever having a first end and a second end;
a probe coupled to the second end of the cantilever, the probe having a tapered tip comprising a ferrimagnetic material;
a motion detector adapted for detecting deflection of the cantilever; and
a heat source adapted for heating the probe.

21. The magnetic force microscope of claim 19, wherein the heat source is a time-varying heat source adapted to modulate heat to the probe.
